(19) United States
(12) Patent Application Publication
(10) Pub. No.: US 2026/0344009 A1
(43) Pub. Date: Oct. 29, 2026

(54) GATE STRUCTURES OF TRANSISTORS WITH REDUCED LEAKAGES AND THE METHODS OF FORMING THE SAME

(71) Applicant: Taiwan Semiconductor Manufacturing Co., Ltd., Hsinchu (TW)

(72) Inventors: Hsin-Yi Lee, Hsinchu (TW); Chi-Ang Tseng, Hsinchu (TW); Yu-An Hsueh, Hsinchu (TW); Tai-Wei Hwang, Kinmen County (TW); Da-Yuan Lee, Jhubei City (TW); Chi On Chui, Hsinchu (TW)

(21) Appl. No.: 19/280,318

(22) Filed: Jul. 25, 2025

Related U.S. Application Data
(60) Provisional application No. 63/796,733, filed on Apr. 29, 2025.

(51) Int. Cl. H10D 84/01; H10D 84/85

(52) U.S. Cl. CPC H10D 84/0177; H10D 84/017; H10D 84/0186; H10D 84/851

(57) ABSTRACT

A method includes forming a source/drain feature aside of a semiconductor region, forming an interlayer dielectric (ILD) layer over the source/drain feature, forming a source/drain contact in the ILD layer to electrically couple to the source/drain feature, and forming a metal silicide layer between the source/drain feature and the source/drain contact. An electrical conductivity of the metal silicide layer is between the electrical conductivity values of the source/drain feature the source/drain contact. The metal silicide layer has a curved profile. The method further comprises forming a replacement gate stack comprising forming an interfacial layer over the semiconductor region, forming a high-k dielectric layer over the interfacial layer, forming an insertion layer contacting the high-k dielectric layer, wherein the insertion layer comprises a metal oxide or silicon oxide, and forming a work-function layer over the high-k dielectric layer and the insertion layer.

### PRIORITY CLAIM AND CROSS-REFERENCE

This application claims the benefit of the following provisionally filed U.S. Patent application: Application No. 63/796,733, filed on Apr. 29, 2025, and entitled “Gate Structure,” which application is hereby incorporated herein by reference.

### BACKGROUND

Semiconductor devices are used in a variety of electronic applications Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 10C, 11A, 11B, 12A, 12B, 13-19, 20A, 20B, 21A, 21B, 22A, 22B, 23A, and 23B illustrate the intermediate stages in the formation of Gate-All-Around (GAA) transistors in accordance with some embodiments.

FIGS. 24 and 25 illustrate gate structures in accordance with alternative embodiments.

FIG. 26 illustrates the distribution of elements in gate structures in accordance with some embodiments.

FIGS. 27 and 28 illustrate the effect of insertion layers to the performance of transistors in accordance with some embodiments.

FIG. 29 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of reducing the diffusion of aluminum in gate stacks and the resulting transistors are provided. In accordance with some embodiments of the present disclosure, an insertion layer is inserted in a gate stack, and may be inserted between a high-k dielectric layer and a work-function layer of the gate stack. The insertion layer may comprise a metal oxide or silicon oxide, and thus has the function of blocking aluminum from diffusing into the underlying high-k dielectric layer. The aluminum atoms diffused into the high-k dielectric layer may cause the increase in leakage current between a gate electrode and a channel region of the transistor. Accordingly, by forming the insertion layer, the leakage current is reduced.

It is appreciated that although Gate-All-Around (GAA) transistors are used as an example, the concept of the present disclosure may be applied to other types of transistors such as planar transistors, Fin Field-Effect Transistors (FinFETs), Complementary Field-Effect Transistors (CFETs), and the like.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

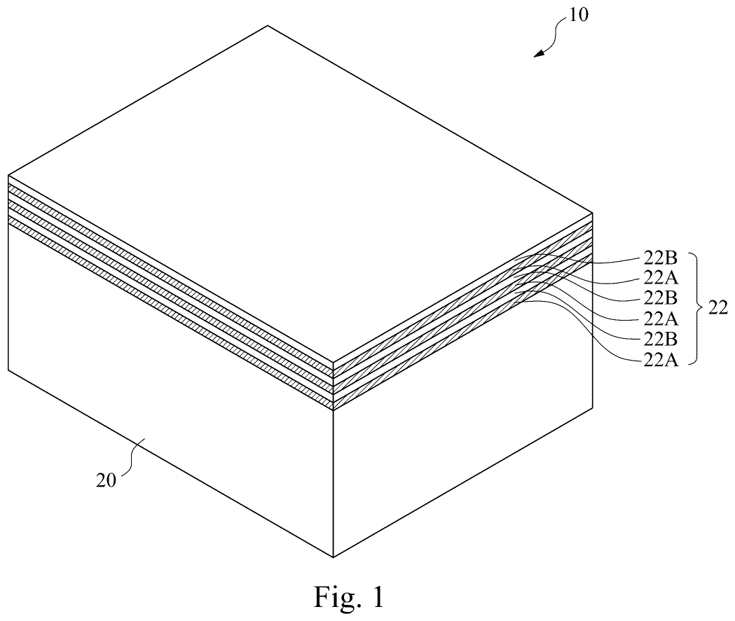

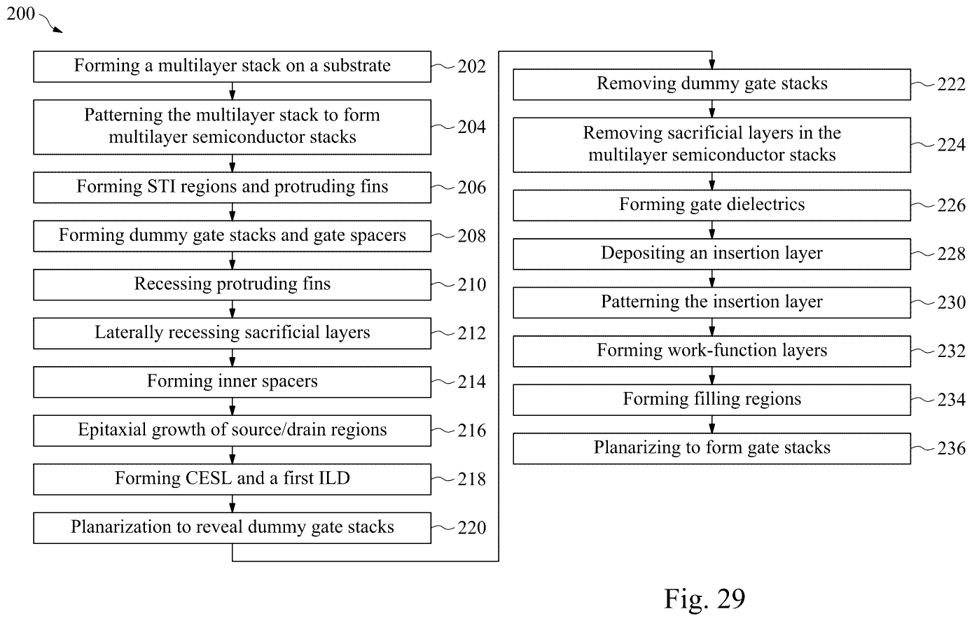

FIGS. 1-4, 5A, 5B, 6A, 6B, 7A, 7B, 8A, 8B, 9A, 9B, 10A, 10B, 10C, 11A, 11B, 12A, 12B, 13-19, 20A, 20B, 21A, 21B, 22A, 22B, 23A, and 23B illustrate the intermediate stages in the formation of GAA transistors in accordance with some embodiments. The respective processes are shown in the process flow 200 as shown in FIG. 29.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 29. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

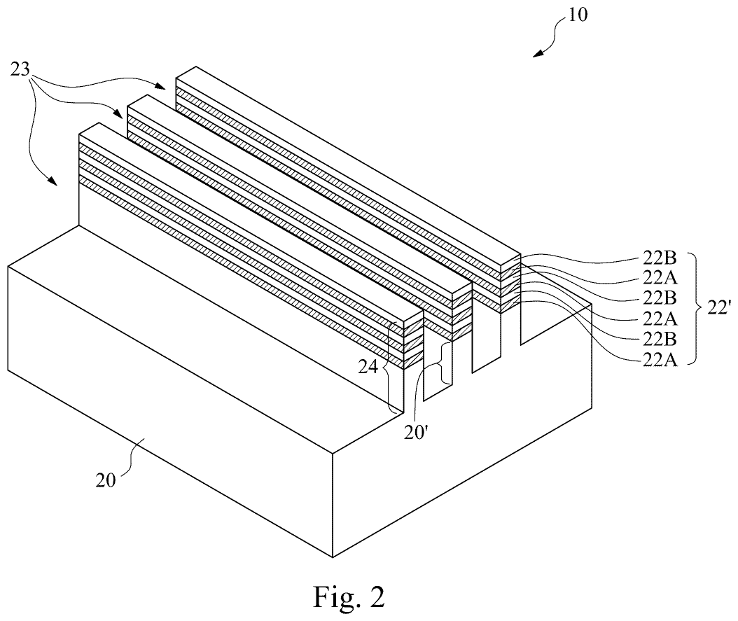

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 29. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

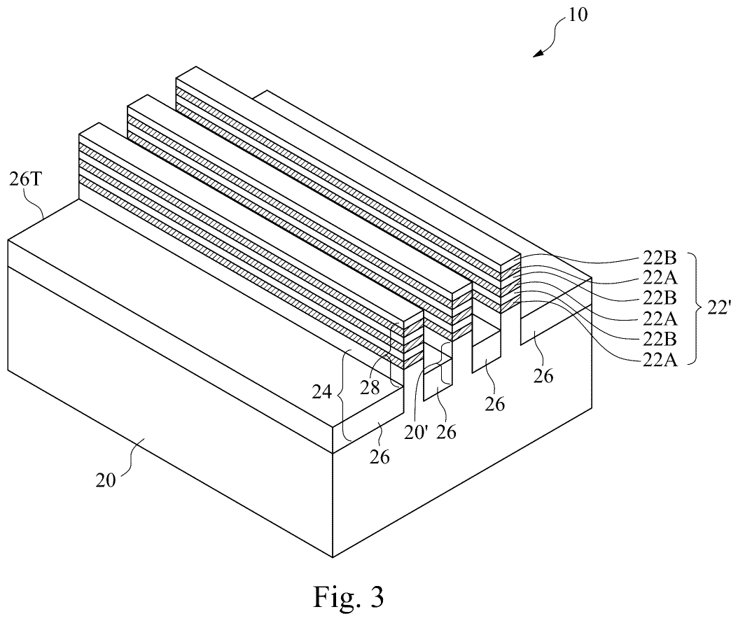

FIG. 3 illustrates the formation of isolation regions 26, which are also referred to as Shallow Trench Isolation (STI) regions throughout the description. The respective process is illustrated as process 206 in the process flow 200 shown in FIG. 29. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

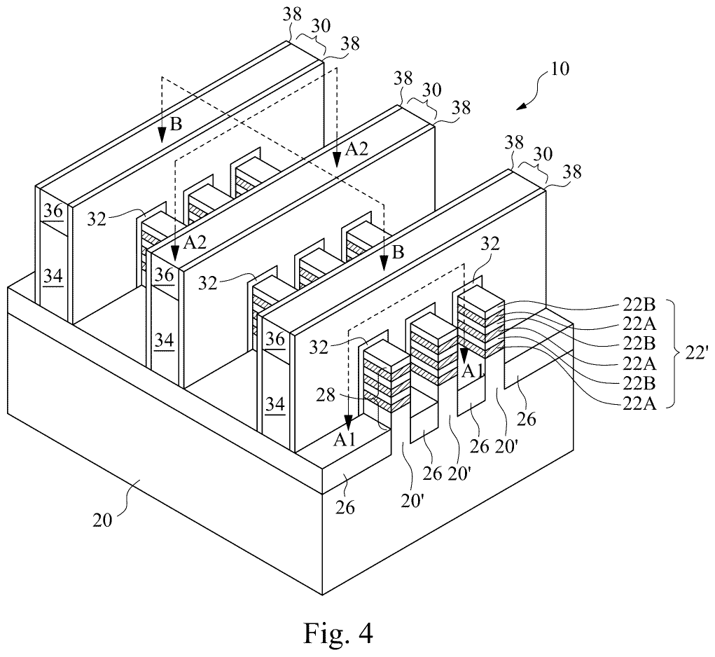

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 29. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

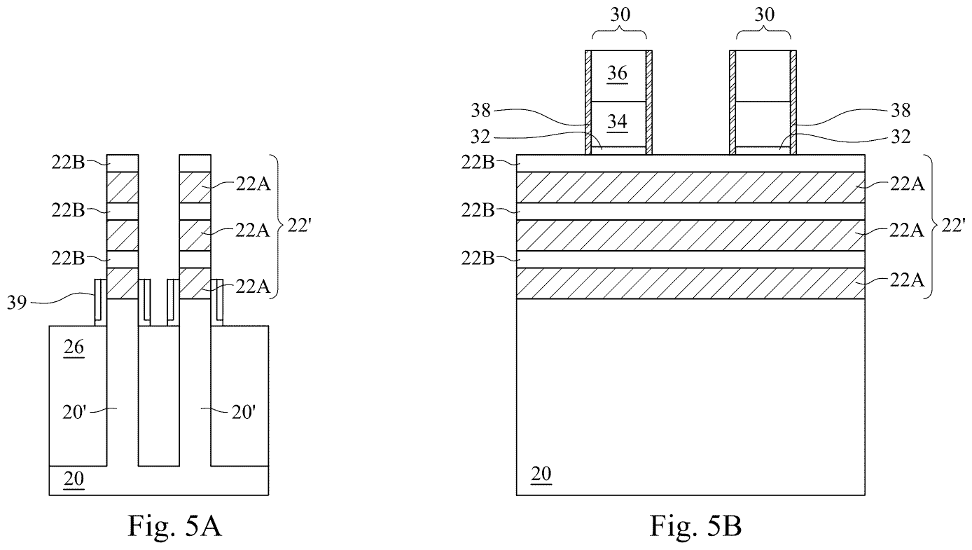

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28. Fin spacers 39 are also illustrated.

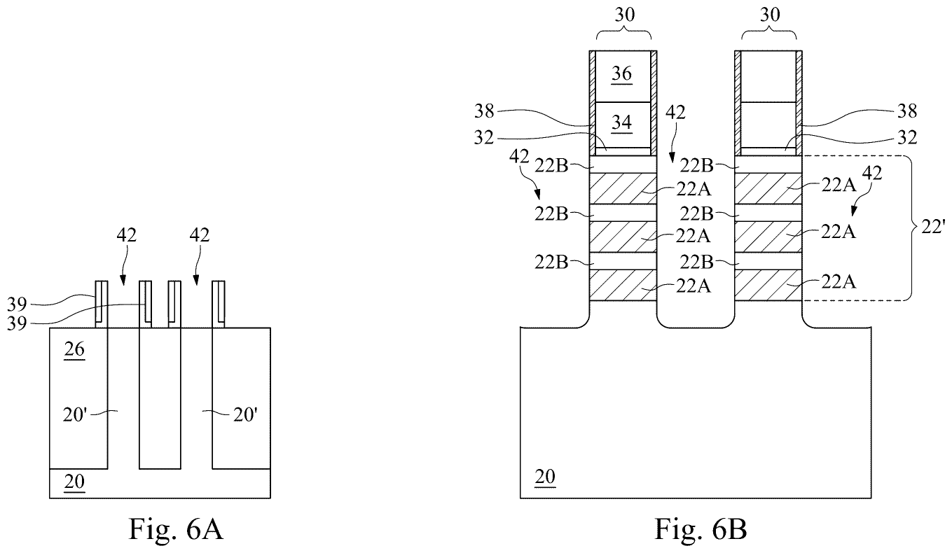

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown in FIG. 29. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

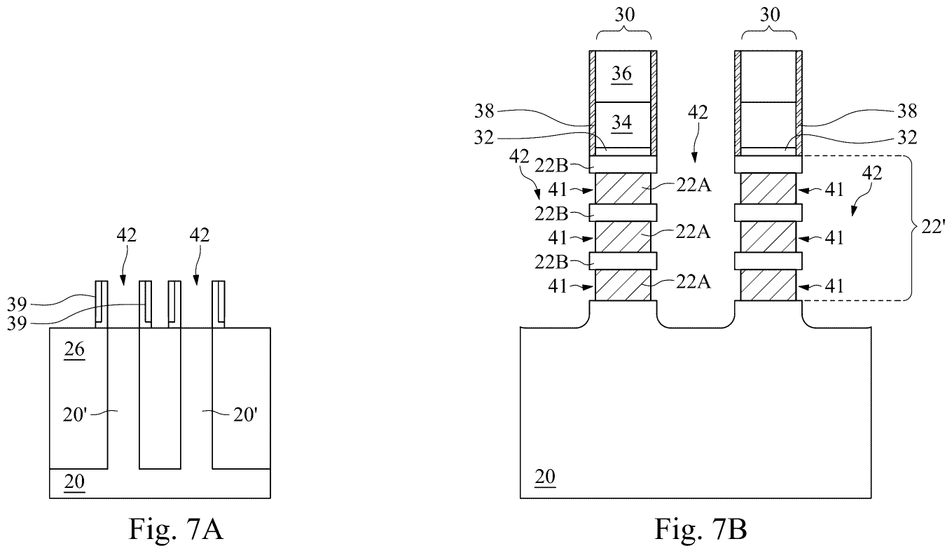

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown in FIG. 29.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, or the like, and may be performed using any suitable process temperatures (for example, between about 400 °C and about 600 °C) and a suitable process time (for example, between about 100 seconds and about 1,000 seconds).

In accordance with alternative embodiments, the lateral recessing of sacrificial semiconductor layers 22A is performed through an isotropic dry etching process or a combination of a dry etching process and a wet etching process.

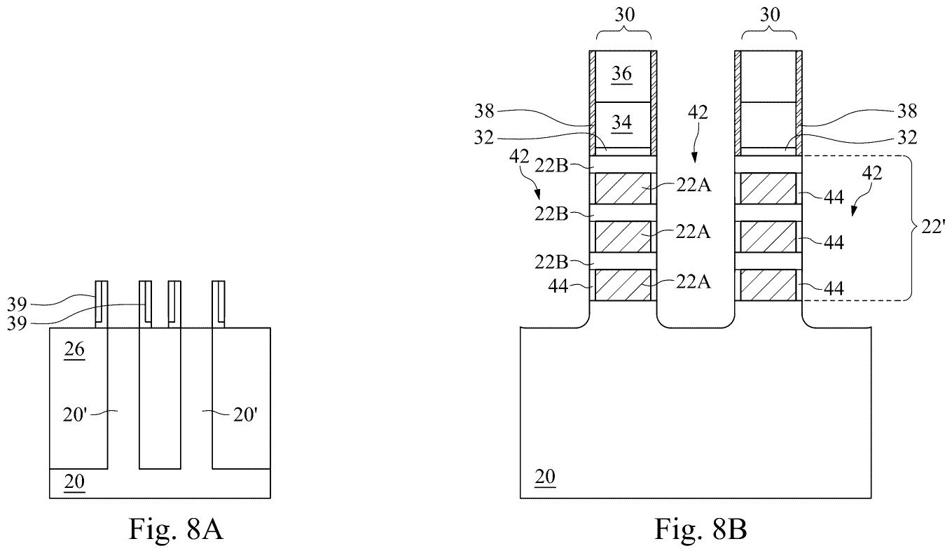

FIGS. 8A and 8B illustrate the formation of inner spacers 44. The respective process is illustrated as process 214 in the process flow 200 shown in FIG. 29. The formation process incudes depositing a spacer layer extending into recesses 41, and performing an etching process to remove the portions of inner spacer layer outside of recesses 41, thus leaving inner spacers 44 in recesses 41. Inner spacers 44 may be formed of or comprise SiOCN, SiON, SiOC, SiCN, or the like. Inner spacers 44 may also be porous so that they have a lower-k value lower than, for example, about 3.5. In accordance with some embodiments, the etching of the spacer layer may be performed through a wet etching process, in which the etching chemical may include H₂SO₄, diluted HF, ammonia solution (NH₄OH, ammonia in water), or the like, or combinations thereof.

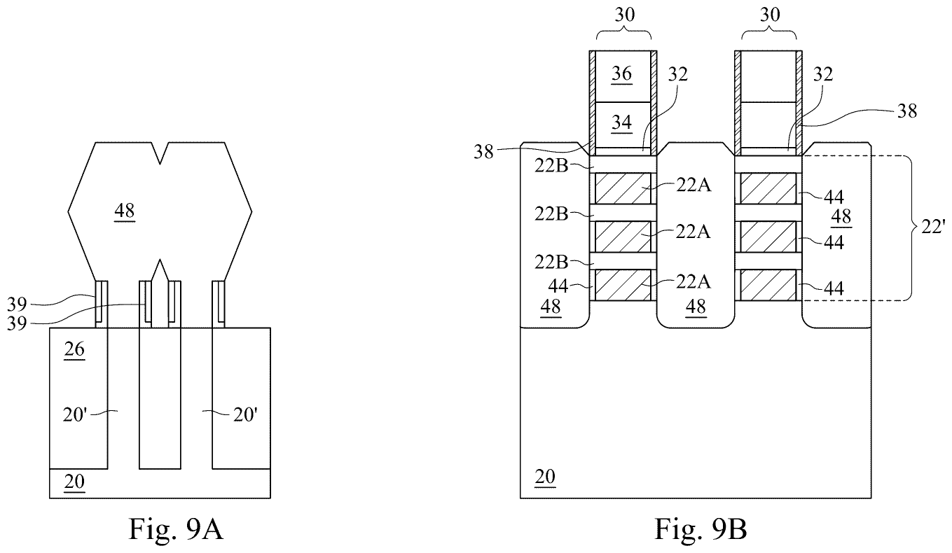

Referring to FIGS. 9A and 9B, epitaxial source/drain regions 48 are formed in recesses 42. The respective process is illustrated as process 216 in the process flow 200 shown in FIG. 29. In accordance with some embodiments, the source/drain regions 48 may exert stress on the nanostructures 22B, which are used as the channels of the corresponding GAA transistors, thereby improving performance. In accordance with some embodiments, the corresponding transistor is n-type, and epitaxial source/drain regions 48 are accordingly formed as of n-type by doping an n-type dopant. For example, silicon phosphorous (SiP), silicon carbon phosphorous (SiCP), or the like may be grown to form epitaxial source/drain regions 48.

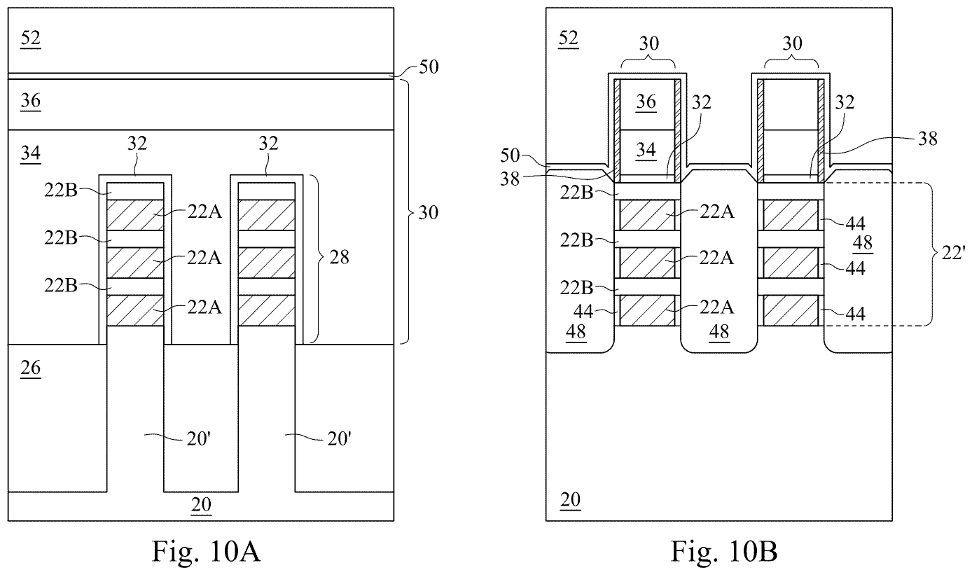

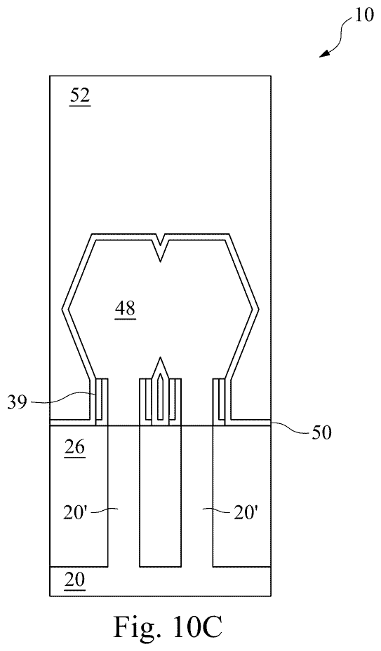

FIGS. 10A, 10B, and 10C illustrate the cross-sectional views of the structure after the formation of Contact Etch Stop Layer (CESL) 50 and Inter-Layer Dielectric (ILD) 52. FIGS. 10A, 10B, and 10C are obtained from the same cross-section same as the cross-sections A2-A2, B-B, and A1-A1, respectively, in FIG. 4. The respective process is illustrated as process 218 in the process flow 200 shown in FIG. 29. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material such as silicon oxide, Phospho-Silicate Glass (PSG), Boro-Silicate Glass (BSG), Boron-Doped Phospho-Silicate Glass (BPSG), Undoped Silicate Glass (USG), or the like.

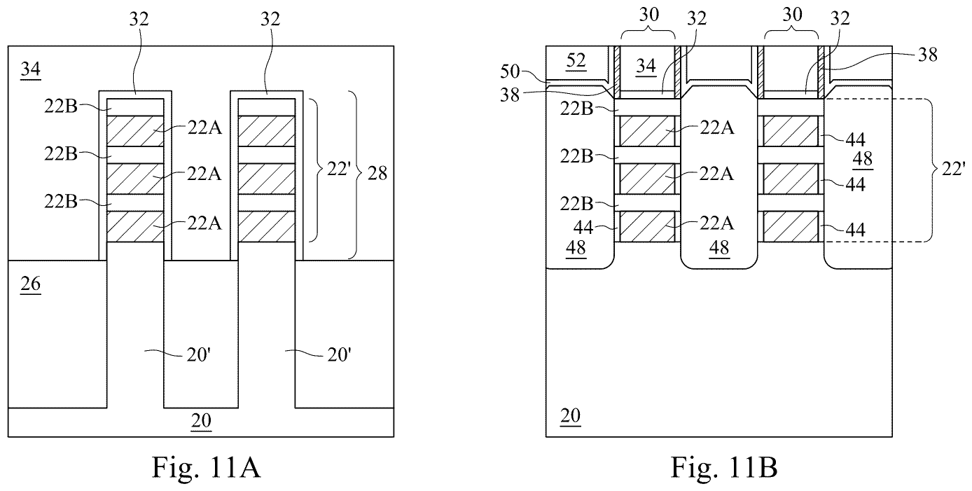

In subsequent processes, replacement gate stacks are formed to replace dummy gate stacks 30. Portions of the gate stacks and spacers are over the nanostructures 22B, which form channel regions. Referring to FIGS. 11A and 11B, a planarization process such as a CMP process or a mechanical grinding process is performed to level the top surface of ILD 52. The respective process is illustrated as process 220 in the process flow 200 shown in FIG. 29.

In accordance with some embodiments, the planarization process may remove hard masks 36 to reveal dummy gate electrodes 34, as shown in FIG. 11B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level with each other within process variations.

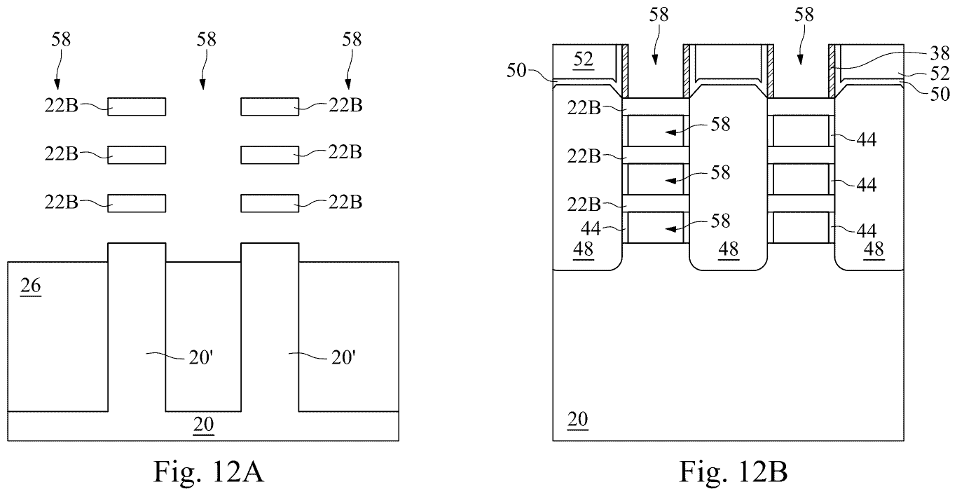

Next, dummy gate electrodes 34 (and hard masks 36, if remaining) are removed in one or more etching processes, so that recesses 58 are formed, as shown in FIGS. 12A and 12B. The respective process is illustrated as process 222 in the process flow 200 shown in FIG. 29. The portions of the dummy gate dielectrics 32 in recesses 58 are also removed. Each recess 58 exposes and/or overlies portions of multilayer stacks 22′, which include the future channel regions in subsequently completed nano-FETs. The corresponding portions of the multilayer stacks 22′ are between neighboring pairs of the epitaxial source/drain regions 48.

Sacrificial layers 22A are then removed to extend recesses 58 between nanostructures 22B. The respective process is illustrated as process 224 in the process flow 200 shown in FIG. 29. Sacrificial layers 22A may be removed by performing an isotropic etching process such as a wet etching process using etchants which are selective to the materials of sacrificial layers 22A. Nanostructures 22B, substrate 20, STI regions 26 remain relatively un-etched as compared to sacrificial layers 22A.

In accordance with some embodiments in which sacrificial layers 22A include, for example, SiGe, and nanostructures 22B include, for example, Si or SiC, the etching chemical such as tetra methyl ammonium hydroxide (TMAH), ammonium hydroxide (NH₄OH), or the like may be used to remove sacrificial layers 22A.

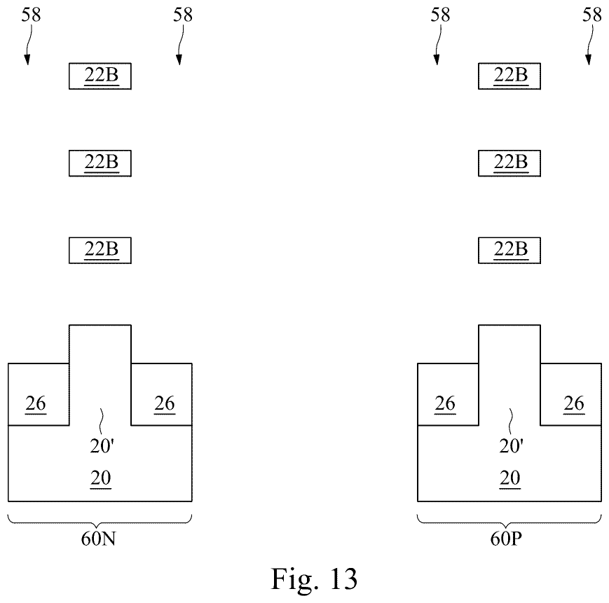

The preceding processes may be used for forming multiple GAA transistors with in different device regions. In subsequent discussion, two device regions are illustrated, each for forming a transistor therein. For example, FIG. 13 illustrates device regions 60N and 60P, and the structures shown therein are formed using the processes as discussed in preceding paragraphs.

In accordance with some embodiments, device region 60N is an n-type transistor region in which an n-type transistor is to be formed, and device region 60P is a p-type transistor region in which a p-type transistor is to be formed. In accordance with other embodiments, both of device regions 60N and 60P may be n-type transistor regions, or both of device regions 60N and 60P may be p-type transistor regions. In accordance with yet other embodiments, the device regions 60N and 60P are n-type transistor region and p-type transistor region, respectively.

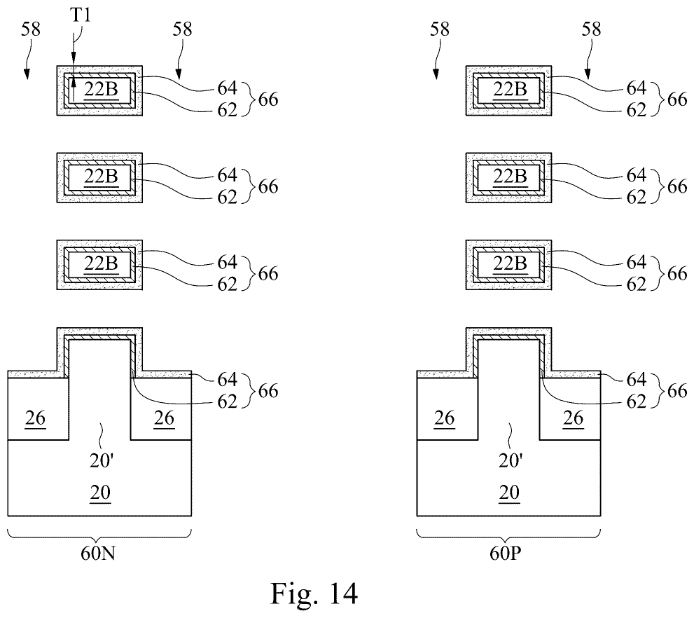

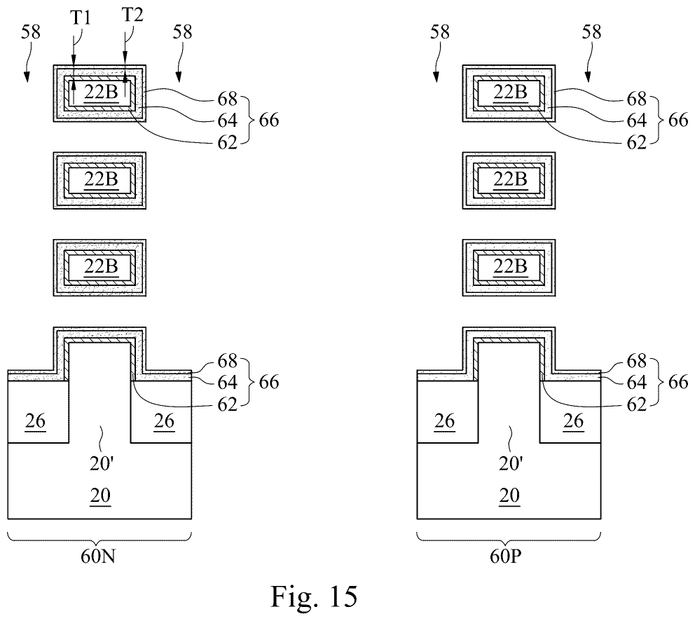

Referring to FIG. 14, gate dielectrics 66 are formed to encircle semiconductor nanostructures 22B. The respective process is illustrated as process 226 in the process flow 200 shown in FIG. 29. The thickness of the gate spacer 38 (FIG. 12B) may be greater than a thickness of the gate dielectrics 66 (which include the insertion layer 68 as subsequently discussed). The gate dielectrics 66 in device regions 60N and 60P may be formed simultaneously (and sharing common processes).

In accordance with some embodiments, each of gate dielectrics 66 includes an interfacial layer 62 and a high-k dielectric layer 64 on the interfacial layer 62. The interfacial layer 62 may be formed of or comprise silicon oxide, which may be deposited through a conformal deposition process such as ALD or CVD. In accordance with alternative embodiments, interfacial layer 62 is formed through thermal oxidation. When formed through thermal oxidation, the portions of interfacial layer 62 on the top surfaces of STI regions 26 will not be formed.

In accordance with some embodiments, the high-k dielectric layer 64 comprises one or more (sub) dielectric layers. The high-k dielectric layer 64 may include a metal oxide or a silicate of hafnium, zirconium, lanthanum, manganese, barium, combinations thereof, and/or multi-layers thereof. The dielectric constant (k value) of high-k dielectric layer 64 may be greater than about 20, for example. High-k dielectric layer 64 is deposited through a conformal deposition process such as ALD or CVD. The thickness T1 of high-k dielectric layer 64 may be in the range between about 15 Å and about 25 Å.

In accordance with some embodiments, an n-type dipole dopant such as La, Sr, Y, Er, Sc, Mg, or the like, or combinations thereof is doped into the high-k dielectric layer 64 in the device region(s) (such as device region 60N) in which an n-type transistor(s) is to be formed. The n-type dipole dopant, when incorporated into the gate dielectrics of n-type transistors, may reduce the threshold voltages of the n-type transistors. The doping process may include depositing a dipole film comprising the n-type dopant over the high-k dielectric layer 64, annealing to drive the n-type dipole dopant into the high-k dielectric layer 64, and removing the dipole film.

A p-type dipole dopant such as La, Sr, Y, Er, Sc, Mg, or the like, or combinations thereof may be doped into the high-k dielectric layer 64 in the device region(s) (such as device region 60N) in which a p-type transistor(s) is to be formed. The p-type dipole dopant may also be doped into the high-k dielectric layer 64 in the device region(s) (such as device region 60P) in which a p-type transistor(s) is to be formed to reduce the threshold voltage of the p-type transistors.

Referring to FIG. 15, insertion layer 68 is formed as a dielectric layer. The dielectric material of insertion layer 68 is different from the material of high-k dielectric layer 64. The respective process is illustrated as process 228 in the process flow 200 shown in FIG. 29. Portions of the insertion layer 68 may also be considered as parts of gate dielectrics 66. The formation process may include a conformal deposition process such as ALD, CVD, or the like.

In accordance with some embodiments, insertion layer 68 comprises a metal oxide, which may comprise TiOₓ, WOₓ, TaOₓ, NbOₓ, VOₓ, AlOₓ, or the like (with “x” representing relative atomic ratios), combinations thereof, and/or multilayers thereof. In accordance with alternative embodiments, insertion layer 68 comprises silicon oxide.

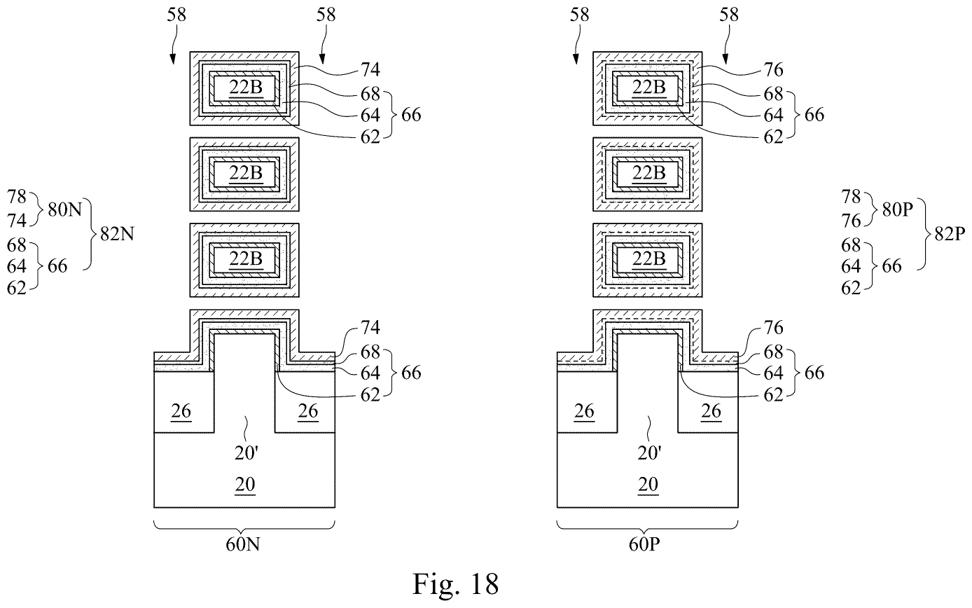

In accordance with some embodiments, the formation of the high-k dielectric layer 64 and the formation of insertion layer 68 may be in-situ performed in a same vacuum environment, without vacuum break in between. Alternatively, there is a vacuum break process between the formation of the high-k dielectric layer 64 and the formation of insertion layer 68. The formation of insertion layer 68 and the subsequent formation of work-function layer 74/76 (FIG. 18), on the other hand, may have (or not have) vacuum break in between.

In accordance with some embodiments in which insertion layer 68 comprises TiOₓ, the formation process may comprise ALD, which is performed using a Ti-containing precursor and an oxidizing agent. The Ti-containing precursor may comprise tetrakis dimethyl-amino titanium (TDEAT), tetrakis diethyl-amino titanium (TDMAT), tetrakis ethyl-methyl-amino titanium (TEMAT), titanium isopropoxide (Ti{OCH(_{CH3})₂}₄)(TTIP), TiCl₄, or the like, or combinations thereof. The oxidizing agent may comprise H₂O, O₃, O₂, and/or the like, and may comprise N₂ and/or NH₃.

The temperature of the corresponding wafer in the formation of insertion layer 68 may be in the range between about 150 °C and about 600 °C. The chamber pressure of the deposition chamber may be in the range between about 0.1 Torr and about 50 Torr.

When insertion layer 68 comprises silicon oxide, the formation process may include soaking the respective wafer in a silicon-containing precursor, so that silicon is adsorbed on high-k dielectric layer 64, and hence a silicon layer is deposited over high-k dielectric layer 64. The silicon-containing precursor may comprise silane, di-silane, or the like, or a combination thereof. A vacuum break process may then be performed, so that silicon is oxidized to form the insertion layer 68 that comprises silicon oxide.

Alternatively, instead of performing the vacuum break process, an oxygen-containing gas such as O₂, O₃, H₂O, or the like may be conducted into the vacuum environment in which the silicon soaking process has been performed to oxidize the silicon. In accordance with yet alternative embodiments, silicon oxide is deposited through ALD, CVD, or the like.

Insertion layer 68 is formed as a thin layer, with thickness T2 being smaller than the thickness T1 of high-k dielectric layer 64. Being thin, insertion layer 68 may perform its function of blocking the diffusion of aluminum, while does not adversely affect the function of gate dielectric 66, and does not reduce the overall dielectric constant of gate dielectrics 66 too much. For example, the thickness T2 of insertion layer 68 may be smaller than about 20 Å. Thickness T2 may also be in the range between about 1 Å and about 20 Å, between about 1 Å and about 10 Å, and possibly between about 3 Å and about 8 Å.

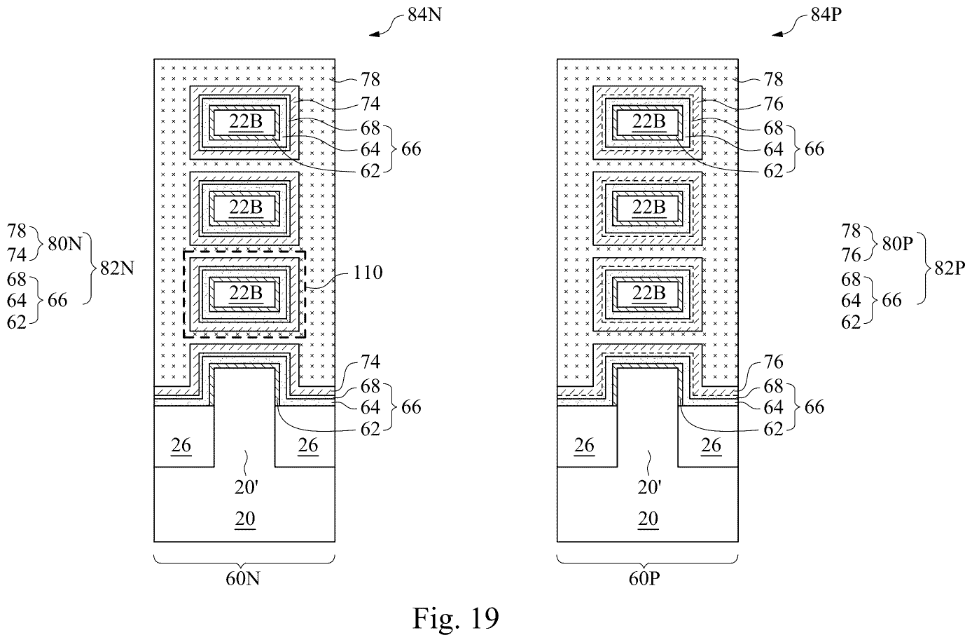

Since the function of insertion layer 68 is to block aluminum, insertion layer 68 may contain aluminum therein. Furthermore, to be effective in blocking aluminum, at a time after the respective transistor is fully formed, the aluminum atomic percentage APAl1 at the (outer) surface of insertion layer 68 contacting the subsequently formed work-function layer 74 (FIG. 19) is higher than the aluminum atomic percentage APAl2 at the (inner) surface of insertion layer 68 contacting high-k dielectric layer 64. For example, the atomic percentage ratio APAl 1/APAl2 may be greater than about 1.5, greater than about 2, or greater than about 5.

The k value of insertion layer 68 may be lower than, equal to, or higher than the dielectric constant of high-k dielectric layer 64. For example, the k value of insertion layer 68 may be equal to or greater than 3.8 (the dielectric constant of silicon oxide), and may be in the range between about 3.8 and about 25, for example, depending on the material.

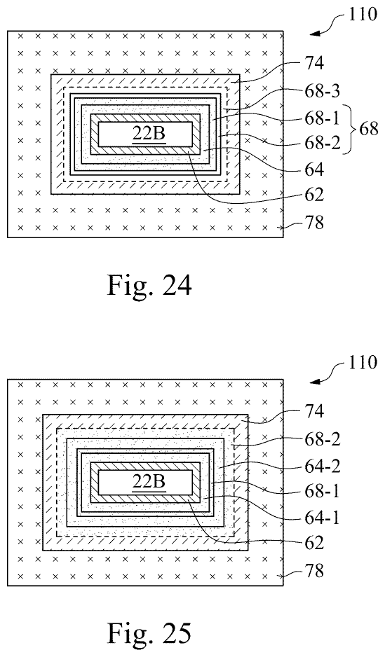

In accordance with some embodiments, insertion layer 68 has a single-layer structure formed of a homogeneous material as aforementioned. In accordance with alternative embodiments, insertion layer 68 may have a multilayer structure including two or more sub-layers. The corresponding structure is illustrated in FIG. 24, and discussed in detail in subsequent paragraphs.

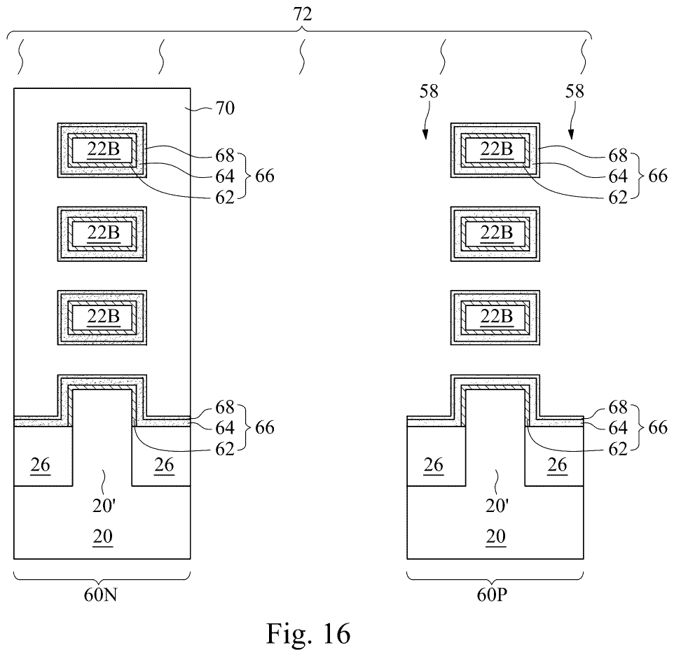

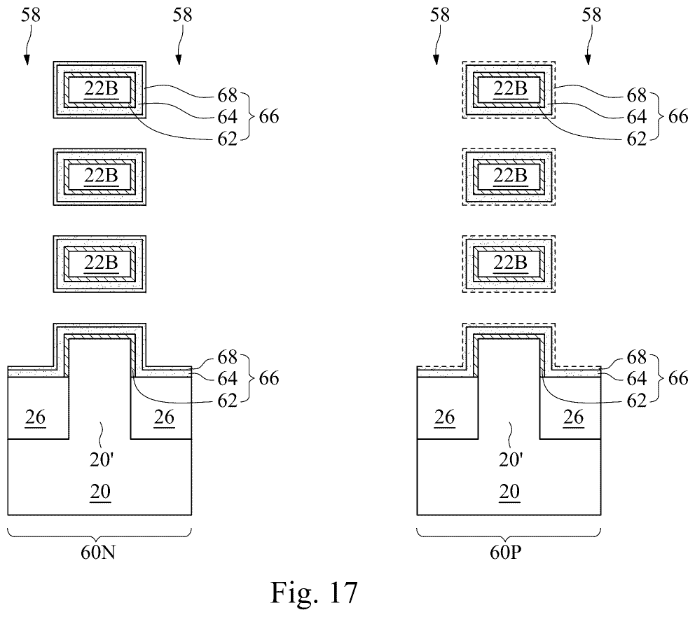

Referring to FIG. 16, a patterned etching mask 70 is formed. In accordance with some embodiments, the patterned etching mask 70 includes a bottom anti-reflective coating (BARC), which is patterned using a top layer that may comprise a patterned photoresist. Next, an etching/patterning process 72 is performed to etch insertion layer 68, so that insertion layer 68 is removed from device region 60P. The respective process is illustrated as process 230 in the process flow 200 shown in FIG. 29. In device region 60N, a remaining portion of the insertion layer 68 remains. After the etching process 72, etching mask 70 is removed. The resulting structure is shown in FIG. 17.

In accordance with alternative embodiments, instead of removing insertion layer 68 from device region 60P, insertion layer 68 is not patterned, and remains in both of device region 60N and 60P. Accordingly, in subsequent figures, insertion layer 68 is shown as being dashed to indicate that the insertion layer 68 may or may not exist in device region 60P.

In accordance with alternative embodiments, instead of depositing insertion layer 68 as a blanket layer and then removing insertion layer 68 from device region 60P, a hard mask (not shown, for example, a BN layer) may be formed over high-k dielectric layer 64, and is removed from device region 60P. A formation process is then performed to form the insertion layer 68. In device region 60N, the insertion layer 68 is deposited over high-k dielectric layer 64. In device region 60P, the insertion layer 68 is deposited over the hard mask. A lift-off process is then performed by etching the hard mask, so that the insertion layer 68 deposited thereon may be removed from device region 60P.

Next, as shown in FIG. 18, work-function layers 74 and 76 are formed in device regions 60N and 60P, respectively. The respective process is illustrated as process 232 in the process flow 200 shown in FIG. 29. In accordance with some embodiments in which device regions 60N and 60P are of opposite conductivity types, work-function layers 74 and 76 may be deposited in different deposition processes, and comprise different materials. In accordance with alternative embodiments in which device regions 60N and 60P are of the same conductivity type (p-type or n-type), work-function layers 74 and 76 may be deposited in the same deposition process.

In accordance with some embodiments, work-function layer 74 is an n-type work function layer comprising an n-type work function material, which has a work function lower than the mid work function (about 4.6 eV, for example). The n-type work-function layer may comprise aluminum, and may include TiAlC, TiAlN, TaAlC, TaAlN, or the like, or combinations thereof. In accordance with some embodiments, while not illustrated, a p-type work-function layer may be formed over the n-type work-function layer 74, with the overall work function being n-type.

Work-function layer 76, when being p-type, may have a high work function higher than the mid work function. The p-type work-function layer 76 may include TiN, TaN, TiSiN, WCN, MOCN, or the combinations thereof. In accordance with some embodiments, while not illustrated, an p-type work-function layer may also be formed over the p-type work-function layer 76, with the overall work function being p-type.

Referring to FIG. 19, a metallic material may be formed to fill the remaining recesses 58 if they have not been fully filled yet to from filling regions 78. The respective process is illustrated as process 234 in the process flow 200 shown in FIG. 29. Filling regions 78 are conductive, and may include a capping layer such as a TiN layer, and a metal-containing material such as cobalt, ruthenium, aluminum, tungsten, combinations thereof, and/or multilayers thereof.

Work-function layer 74 and filling regions 78 are collectively referred to as gate electrode 80N. Gate electrode 80N and the underlying gate dielectric 66 (which includes insertion layer 68 therein) are collectively referred to as gate stack 82N. Work-function layer 76 and filling regions 78 are collectively referred to as gate electrode 80P. Gate electrode 80P and the underlying gate dielectric 66 (which may or may not include insertion layer 68 therein) are collectively referred to as gate stack 82P.

In accordance with alternative embodiments, the recesses 58 have been fully filled, and hence no filling regions 78 are formed.

Transistors 84N and 84P are thus formed in device regions 60N and 60P, respectively. In accordance with some embodiments, transistor 84N is an n-type transistor, and transistor 84P is a p-type transistor. In other embodiments, each of transistors 84N and 84P may be of n-type or p-type in any combination.

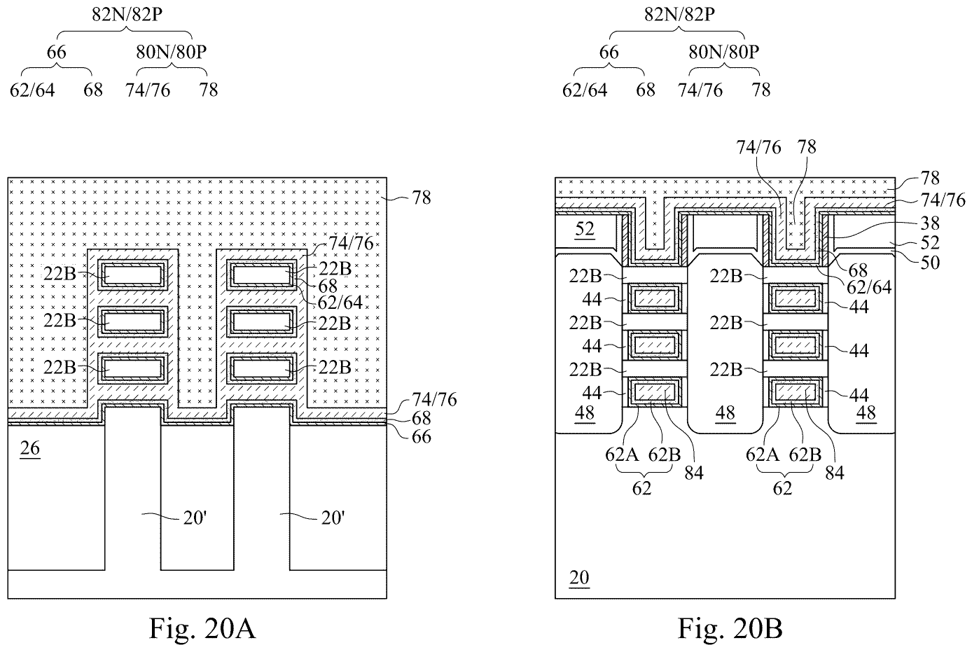

FIGS. 20A and 20B through FIGS. 23A and 23B illustrate the formation of gate stacks and remaining features in accordance with some embodiments. The subsequent figure numbers in FIGS. 20A and 20B through 23A and 23B may have the corresponding numbers followed by letter A or B. The letter A indicates that the corresponding figure shows a cross-section same as the cross-section A2-A2 in FIG. 4, and the letter B indicates that the corresponding figure shows a reference cross-section same as the reference cross-section B-B in FIG. 4.

Each of the structures in device regions 60N and 60P may be formed by the processes in FIGS. 20A and 20B through 23A and 23B to finish the formation of transistors. Accordingly, the formation process as shown in FIGS. 20A and 20B through 23A and 23B may represent the formation of each of the transistors in FIG. 19.

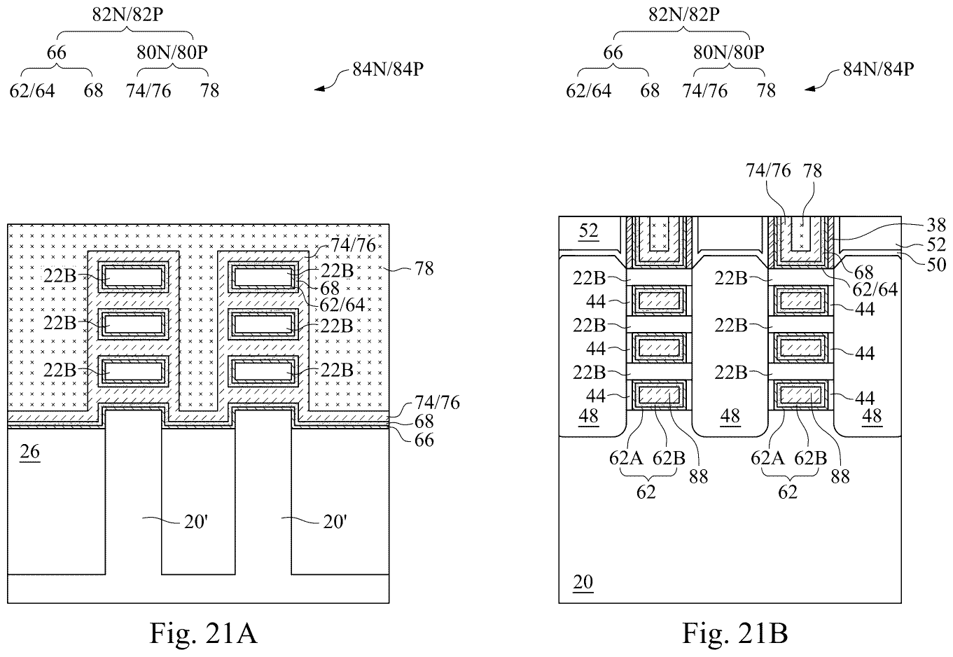

FIGS. 20A and 20B and FIGS. 20A and 20B illustrate the structures and the processes that have been shown and discussed referring to FIG. 19. Referring to FIGS. 20A and 20B, stacked conductive layers (which include work function layers 74/76 and filling regions 78) are deposited. Referring to FIGS. 21A and 21B, a planarization process such as a CMP process or a mechanical grinding process is performed to remove the excess portions of the gate dielectrics and gate electrodes, which excess portions are over the top surface of ILD 52. The respective process is illustrated as process 236 in the process flow 200 shown in FIG. 29. The remaining portions of the planarized layer form gate stacks 82N and 82P, which are denoted as 82N/82P.

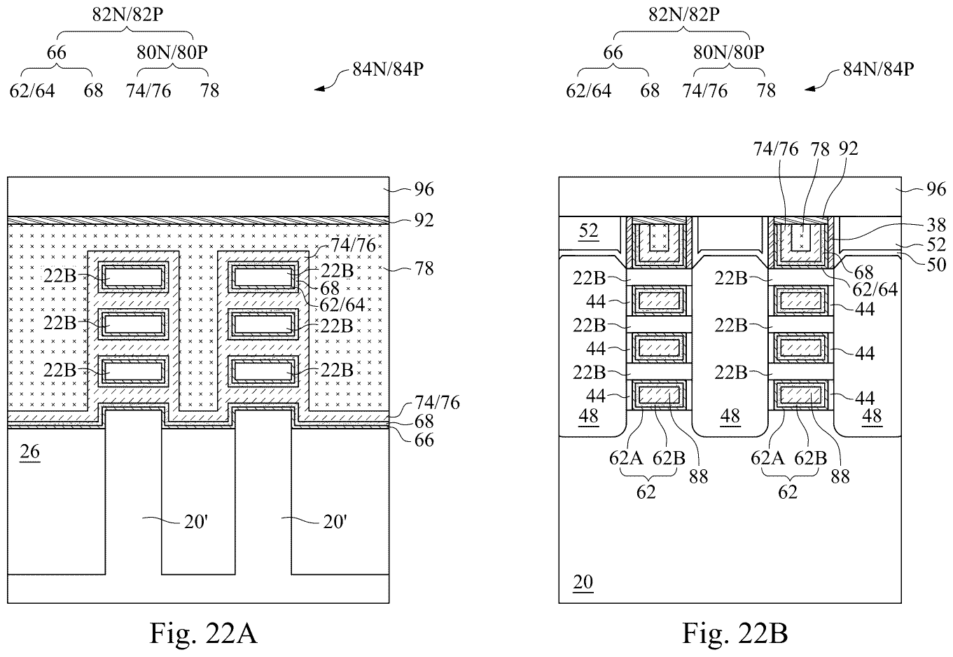

Next, as shown in FIGS. 22A and 22B, gate stacks 82N/82P are recessed, so that recesses are formed directly over gate stacks 82N/82P and between opposing portions of gate spacers 38. Gate masks 92 are then formed by filling one or more layers of dielectric material, such as silicon nitride, silicon oxynitride, or the like into the recesses, followed by a planarization process to remove excess portions of the dielectric material.

As further illustrated by FIGS. 22A and 22B, ILD 96 is deposited over ILD 52 and over gate masks 92. An etch stop layer (not shown) may be, or may not be, deposited before the formation of ILD 96. In accordance with some embodiments, ILD 96 is formed through FCVD, CVD, PECVD, or the like. ILD 96 is formed of a dielectric material, which may be selected from silicon oxide, PSG, BSG, BPSG, USG, or the like.

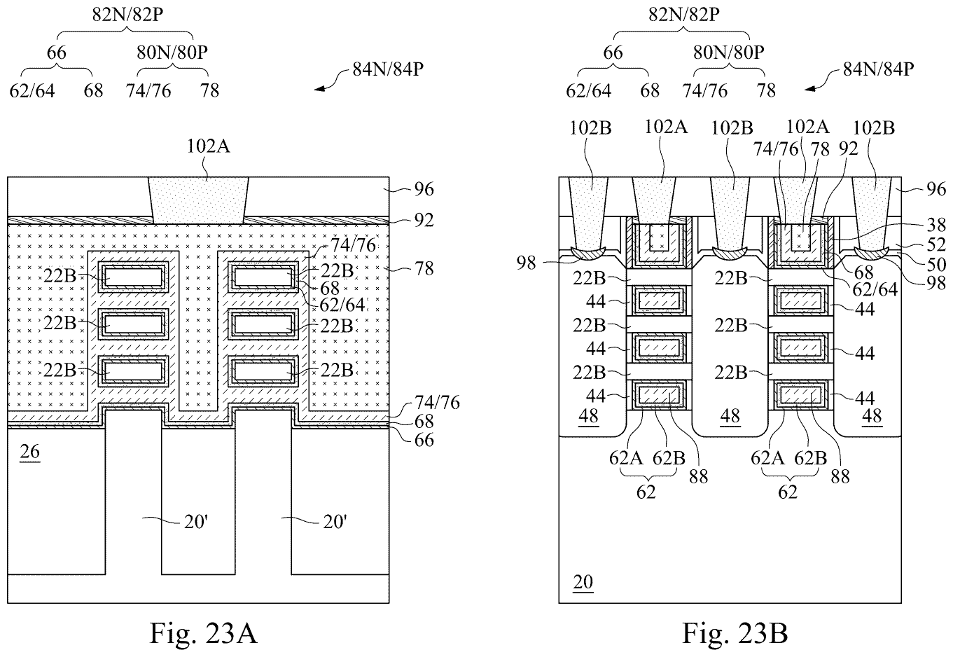

In FIGS. 23A and 23B, ILD 96, ILD 52, CESL 50, and gate masks 92 are etched to form recesses (occupied by contact plugs 102A and 102B), through which the surfaces of the epitaxial source/drain regions 48 and/or gate stacks 82N/82P are exposed. The recesses may be formed through etching using an anisotropic etching process, such as reactive ion etching (RIE), neutral beam etching (NBE), or the like.

After the recesses are formed, silicide regions 98 (FIG. 23B) are formed over the epitaxial source/drain regions 48, and may have curved profiles. Source/drain contact plugs (also referred to as contacts) 102B are then formed over silicide regions 98. The electrical conductivity of the metal silicide regions 98 is between an electrical conductivity of the source/drain regions 48 and an electrical conductivity of the source/drain contact 102A/102B, wherein the metal silicide regions 98 may comprise a curved profile. Also, gate contact plugs 102A are formed in the recesses, and are over and contacting gate electrodes 80N/80P. Although FIG. 23B illustrates that contact plugs 102A and 102B are in a same cross-section, in various embodiments, contact plugs 102A and 102B may be formed in different cross-sections, thereby reducing the risk of shorting with each other.

FIGS. 24 and 25 illustrate the gate stacks 82N in accordance with alternative embodiments. The structure of gate stacks 82P will have similar change per the process shown in FIGS. 13-19. The illustrated region in FIGS. 24 and 25 are in region 110 in FIG. 19. FIG. 24 illustrates the insertion layer 68 in accordance with some embodiments, which has a multilayer structure including sub layers 68-1 and 68-2. There may, or may not be sub layer 68-3. Sub-layers 68-1, 68-2, and 68-3 (if formed) are formed of different materials different from the materials of high-k dielectric layer 64, and the material of sub layer 68-2 is different from the materials of sub-layers 68-1 and 68-3. Each of sub-layers 68-1, 68-2, and 68-3 may be selected from the metal oxide or silicon oxide as above-discussed in any applicable combination.

FIG. 25 illustrates the insertion layer 68 in accordance with some embodiments, wherein insertion layer 68 (denoted as 68-1) is inserted between two high-k dielectric layers 64-1 and 64-2. Each of high-k dielectric layers 64-1 and 64-2 may comprise a metal oxide or a silicate of hafnium, zirconium, lanthanum, manganese, barium, or the like. There may be (or may not be) another insertion layer 68-2 encircling higher-k dielectric layer 64-2.

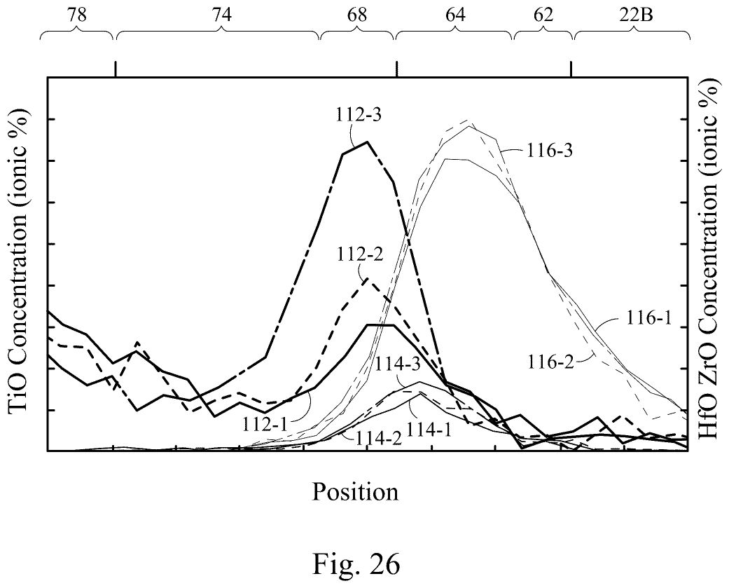

FIG. 26 illustrates the distribution of concentration (atomic/ionic percentage) of TiO (which forms an example insertion layer 68) as functions of positions in accordance with some embodiments. The positions of nanostructure 22B, gate dielectric 66, insertion layer 68, work-function layer 74, and filling regions 78 are marked. The left Y-axis represents the concentrations of TiO, and the right Y-axis represents the concentrations of ZrO or HfO (example materials of high-k dielectric layer 64).

The illustrated distribution of TiO concentrations are obtained from three different samples. The lines 112-1, 112-2, and 112-3 are the concentrations of TiO bonds, which are obtained using Atom Probe Tomography. The lines 112-1, 112-2, and 112-3 are the results that the insertion layer 68 is formed using 0 cycle (meaning no insertion layer is formed), three cycles, and 17 cycles, respectively. When no insertion layer 68 is formed, since the titanium in TiAlC can still form bonds with the oxygen in the high-k dielectric layer 64, the TiO concentration is not equal to zero, but is still lower than the TiO concentrations of 3 ALD cycle TiO and 17 ALD cycle TiO.

Lines 114-1, 114-2, and 114-3 are the concentrations of ZrO bonds (when the high-k dielectric layer 64 comprise ZrO) obtained from different samples. Lines 116-1, 116-2, and 116-3 are the concentrations of HfO bonds (when the high-k dielectric layer 64 comprise HfO) obtained from different samples.

It is appreciated that although the illustrated samples include Ti in different layers (such as in the TiAlC in the n-type work-function layer 74, and the TiN as the capping layer (parts of filling regions 78)), the concentrations of Ti—Al bonds and Ti—N may be distinguished from the Ti—O bonds, and hence the titanium in insertion layer 68, n-type work-function layer 74, and the capping layer in filling regions 78 may still be distinguished from each other. If other methods such as Energy Dispersive Spectroscopy (EDS) is used, while the Ti signal in insertion layer 68, n-type work-function layer 74, and the capping layer in filling regions 78 cannot be distinguished from each other, and will be merged as one line, there may be three distinct peaks of the Ti signal, each in the positions close to the middle point of the corresponding layers, and valleys of the Ti signal between the peaks. Accordingly, the distinctive layers can still be distinguished from each other.

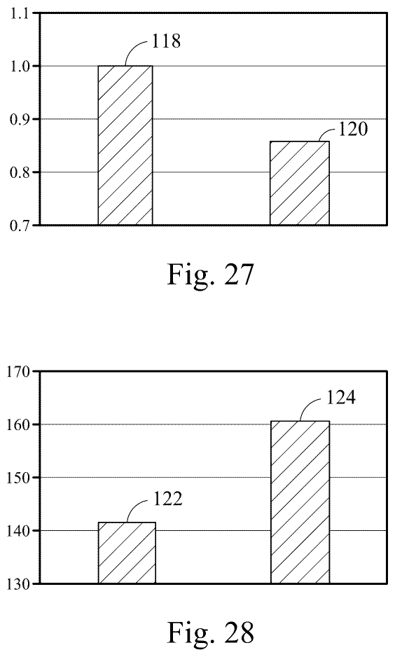

FIG. 27 illustrates the experiment results showing the effect of insertion layer 68 for reducing leakage current between gate electrodes and the corresponding channel region of the transistors. Bar 118 is the leakage current of a transistor without forming the insertion layer. Bar 120 is the leakage current of a transistor having the insertion layer. FIG. 27 shows that with the formation of the insertion layer, the leakage current represented by bar 120 is reduce to 85 percent of the leakage current represented by bar 118.

FIG. 28 illustrates the experiment results showing the effect of the insertion layer for improving dipole tuning effect. Bar 122 is the reduction of threshold voltage by doping an n-type dipole dopant into a high-k dielectric of a first n-type transistor that has no insertion layer. Bar 124 is the reduction of threshold voltage by doping an n-type dipole dopant into a high-k dielectric of a second n-type transistor that has an insertion layer. FIG. 28 shows that with the formation of the insertion layer, when the same n-type dopant is doped, the threshold voltage of the second n-type transistor may be reduced by 20 mV more than the first n-type transistor.

The embodiments of the present disclosure have some advantageous features. By forming an insertion layer between a high-k dielectric layer and an overlying n-type work function layer, which may comprise aluminum, the diffusion of aluminum (which is prone to diffusion) into the corresponding channel region is blocked by the insertion layer. This results in reduced leakage current and improved threshold voltage reduction when dipole doping is adopted.

In accordance with some embodiments of the present disclosure, a method comprises forming a source/drain feature aside of a semiconductor region; forming an ILD layer over the source/drain feature; forming a source/drain contact disposed in the ILD layer to electrically couple to the source/drain feature; and forming a metal silicide layer disposed between the source/drain feature and the source/drain contact, wherein an electrical conductivity of the metal silicide layer is between a first electrical conductivity of the source/drain feature and a second electrical conductivity of the source/drain contact, and wherein the metal silicide layer comprises a curved profile.

The method further comprises forming a replacement gate stack comprising forming an interfacial layer over the semiconductor region; forming a high-k dielectric layer over the interfacial layer; forming an insertion layer contacting the high-k dielectric layer, wherein the insertion layer comprises a metal oxide or silicon oxide; and forming a work-function layer over the high-k dielectric layer and the insertion layer.

In an embodiment, the forming the insertion layer comprises depositing the metal oxide selected from the group consisting of TiOₓ, WOₓ, TaOₓ, NbOₓ, VOₓ, and AlOₓ. In an embodiment, the forming the high-k dielectric layer and the forming the insertion layer are performed in a same vacuum environment without vacuum break therebetween. In an embodiment, the forming the insertion layer comprises forming silicon oxide.

In an embodiment, the forming the insertion layer comprising silicon oxide comprises soaking the high-k dielectric layer in a silicon-containing precursor to deposit a silicon layer; and performing a vacuum break process to oxidize the silicon layer. In an embodiment, the insertion layer has a lower dielectric constant than the high-k dielectric layer. In an embodiment, the insertion layer is between, and contacting, the high-k dielectric layer and the work-function layer.

In an embodiment, the forming the insertion layer comprises depositing the metal oxide, and the metal oxide is between the interfacial layer and the high-k dielectric layer. In an embodiment, the forming the insertion layer comprises forming a first sub-layer and forming a second sub-layer comprising different materials. In an embodiment, the first sub-layer comprises the metal oxide, and the second sub-layer comprises silicon oxide.

In accordance with some embodiments of the present disclosure, a method comprises forming a first interfacial layer over a first semiconductor region; forming a first high-k dielectric layer over the first interfacial layer; forming a second interfacial layer over a second semiconductor region; forming a second high-k dielectric layer over the second interfacial layer; forming an insertion layer comprising a first portion over the first high-k dielectric layer; and a second portion over the second high-k dielectric layer; removing the second portion of the insertion layer; forming a first work-function layer over the first portion of the insertion layer; and forming a second work-function layer over and contacting the second high-k dielectric layer.

In an embodiment, the forming the first work-function layer comprises depositing an aluminum-containing layer. In an embodiment, the forming the insertion layer comprises depositing a metal oxide layer. In an embodiment, the metal oxide layer has a lower dielectric constant than the first high-k dielectric layer.

In an embodiment, the first high-k dielectric layer and the second high-k dielectric layer are formed through a same first deposition process and are formed of a same high-k dielectric material. In an embodiment, the forming the insertion layer comprises forming a silicon oxide layer.

In accordance with some embodiments of the present disclosure, a structure comprises a semiconductor region; a gate dielectric layer comprising an interfacial layer; a high-k dielectric layer over the interfacial layer, the high-k dielectric layer comprising a first dielectric material; and an insertion layer over the high-k dielectric layer, the insertion layer comprising a second dielectric material different from the first dielectric material; a first work-function layer over the insertion layer; and a source/drain region aside of the gate dielectric layer. In an embodiment, the first work-function layer comprises aluminum therein. In an embodiment, the insertion layer comprises a metal oxide. In an embodiment, the insertion layer comprises silicon oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
performing an epitaxy process to grow a source/drain feature aside of a semiconductor region;
depositing an interlayer dielectric (ILD) layer over the source/drain feature;
forming a source/drain contact disposed in the ILD layer to electrically couple to the source/drain feature;
forming a metal silicide layer disposed between the source/drain feature and the source/drain contact, wherein an electrical conductivity of the metal silicide layer is between a first electrical conductivity of the source/drain feature and a second electrical conductivity of the source/drain contact, wherein the metal silicide layer comprises a curved profile; and
forming a replacement gate stack comprising:
forming an interfacial layer over the semiconductor region;
forming a high-k dielectric layer over the interfacial layer;
forming an insertion layer contacting the high-k dielectric layer, wherein the insertion layer comprises a metal oxide or silicon oxide; and
depositing a work-function layer over the high-k dielectric layer and the insertion layer.

2. The method of claim 1, wherein the forming the insertion layer comprises depositing the metal oxide selected from the group consisting of TiOₓ, WOₓ, TaOₓ, NbOₓ, VOₓ, and AlOₓ.

3. The method of claim 2, wherein the forming the high-k dielectric layer and the forming the insertion layer are performed in a same vacuum environment without vacuum break therebetween.

4. The method of claim 1, wherein the forming the insertion layer comprises forming silicon oxide.

5. The method of claim 4, wherein the forming the insertion layer comprising silicon oxide comprises:
soaking the high-k dielectric layer in a silicon-containing precursor to deposit a silicon layer; and
performing a vacuum break process to oxidize the silicon layer.

6. The method of claim 1, wherein the insertion layer has a lower dielectric constant than the high-k dielectric layer.

7. The method of claim 1, wherein the insertion layer is in physical contact with the work-function layer.

8. The method of claim 1, wherein the forming the insertion layer comprises depositing the metal oxide, and the metal oxide is between the interfacial layer and the high-k dielectric layer.

9. The method of claim 1, wherein the forming the insertion layer comprises forming a first sub-layer and forming a second sub-layer comprising different materials.

10. The method of claim 9, wherein the first sub-layer comprises the metal oxide, and the second sub-layer comprises silicon oxide.

11. A method comprising:
forming a first interfacial layer over a first semiconductor region;
forming a first high-k dielectric layer over the first interfacial layer;
forming a second interfacial layer over a second semiconductor region;
forming a second high-k dielectric layer over the second interfacial layer;
forming an insertion layer comprising:
a first portion over the first high-k dielectric layer; and
a second portion over the second high-k dielectric layer;
removing the second portion of the insertion layer;
forming a first work-function layer over the first portion of the insertion layer; and
forming a second work-function layer over and contacting the second high-k dielectric layer.

12. The method of claim 11, wherein the forming the first work-function layer comprises depositing an aluminum-containing layer.

13. The method of claim 11, wherein the forming the insertion layer comprises depositing a metal oxide layer.

14. The method of claim 13, wherein the metal oxide layer has a lower dielectric constant than the first high-k dielectric layer.

15. The method of claim 11, wherein the first high-k dielectric layer and the second high-k dielectric layer are formed through a same first deposition process and are formed of a same high-k dielectric material.

16. The method of claim 11, wherein the forming the insertion layer comprises forming a silicon oxide layer.

17. A structure comprising:
a semiconductor region;
a gate dielectric layer comprising:
an interfacial layer;
a high-k dielectric layer over the interfacial layer, the high-k dielectric layer comprising a first dielectric material; and
an insertion layer over the high-k dielectric layer, the insertion layer comprising a second dielectric material different from the first dielectric material;
a first work-function layer over the insertion layer; and
a source/drain region aside of the gate dielectric layer.

18. The structure of claim 17, wherein the first work-function layer comprises aluminum.

19. The structure of claim 17, wherein the insertion layer comprises a metal oxide.

20. The structure of claim 17, wherein the insertion layer comprises silicon oxide.
